(19) United States
(12) Patent Application Publication
(10) Pub. No.: US 2023/0063378 A1
(43) Pub. Date: Mar. 2, 2023

(54) KEYBOARD APPARATUS WITH CHANGEABLE KEY DISPLAYS

(71) Applicant: Acer Incorporated, New Taipei City (TW)

(72) Inventors: Jui-Chieh Hsiang, New Taipei City (TW); Hsu-Hsiang Tseng, New Taipei City (TW); Chih-Chiang Chen, New Taipei City (TW); Ruey-Ching Shyu, New Taipei City (TW); Kung-Cheng Lin, New Taipei City (TW)

(73) Assignee: Acer Incorporated, New Taipei City (TW)

(21) Appl. No.: 17/506,692

(22) Filed: Oct. 21, 2021

(30) Foreign Application Priority Data
Aug. 25, 2021 (TW) 110131445

(51) Int. Cl. G06F 3/02; G06F 3/147; G06F 3/044

(52) U.S. Cl. CPC G06F 3/021; G06F 3/0219; G06F 3/147; G06F 3/0445

(57) ABSTRACT

The disclosure provides a keyboard apparatus, which includes a printed circuit board (PCB), a keyboard module, and a display film. The PCB includes at least one lower pixel electrode disposed on the PCB. The keyboard module includes a transparent substrate, at least one upper pixel electrode, and multiple key mechanisms. The upper pixel electrode and the key mechanisms are disposed on the transparent substrate. The display film is disposed between the PCB and the keyboard module. The display film is adapted to be driven by the upper pixel electrode and the lower pixel electrode to display at least one image, where the image is suitable for presentation through any one of the key mechanisms. The display film includes a bistable display material or an electronic paper material. A first display substrate and a second display substrate of the display film are different from the PCB and the transparent substrate.

### CROSS-REFERENCE TO RELATED APPLICATION

This application claims the priority benefit of Taiwanese application serial no. 110131445, filed on Aug. 25, 2021. The entirety of the above-mentioned patent application is hereby incorporated by reference herein and made a part of this specification.

### BACKGROUND

### Technical Field

The disclosure relates to a keyboard, and in particular to a keyboard apparatus with changeable key displays.

### Description of Related Art

Keyboards are commonly used as human-machine interface devices. Generally, keyboards have multiple keys with different functions, and the upper surface of each key is printed with text, symbols, and/or graphics. In many applications, the user can define the keys of the keyboard (change their function). In any case, although the definition/function of a key is changed, a normal keyboard cannot dynamically change the display/label of a key.

### SUMMARY

The disclosure provides a keyboard apparatus having a changeable key display function.

According to an embodiment of the disclosure, the keyboard apparatus includes a printed circuit board, a keyboard module, and a display film. The printed circuit board includes at least one lower pixel electrode disposed on the printed circuit board. The keyboard module includes a transparent substrate, at least one upper pixel electrode, and multiple key mechanisms. The upper pixel electrode and the key mechanisms are disposed on the transparent substrate. The display film is disposed between the printed circuit board and the keyboard module. The display film is adapted to be driven by the upper pixel electrode and the lower pixel electrode to display at least one image, where the image is suitable for presentation through any of the key mechanisms. The display film includes a first display substrate, a second display substrate, and a display layer. The display layer is disposed between the first display substrate and the second display substrate.

The first display substrate and the second display substrate are different from the printed circuit board and the transparent substrate.

Based on the foregoing, the keyboard apparatus according to the embodiments of the disclosure has a display film. Multiple key mechanisms of the keyboard module may share the display film, i.e., the display film may present images through any of the key mechanisms. When a system changes a definition (function) of a key, the system may change an image/graphic presentation of the key by driving the display film. Therefore, the keyboard apparatus has a changeable key display function.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a schematic view of a circuit block of a keyboard apparatus according to an embodiment of the disclosure.

FIG. 2 is an exploded schematic view of a keyboard apparatus according to an embodiment of the disclosure.

FIG. 3 is a schematic view of a layout of a transparent substrate of a keyboard module according to an embodiment of the disclosure.

FIG. 4 is a schematic cross-sectional view of a key mechanism of a keyboard module according to an embodiment of the disclosure.

FIG. 5 is a schematic cross-sectional view illustrating a keycap shown in FIG. 4 in an unpressed state according to an embodiment of the disclosure.

FIG. 6 is a schematic view illustrating an equivalent circuit of the key mechanism, a display film, and a printed circuit board shown in FIG. 4 according to an embodiment of the disclosure.

FIG. 7 is a schematic cross-sectional view illustrating the keycap shown in FIG. 4 in a pressed state according to an embodiment of the disclosure.

FIG. 8 is a schematic cross-sectional view of a key mechanism of a keyboard module according to another embodiment of the disclosure.

FIG. 9 is a schematic cross-sectional view illustrating a keycap shown in FIG. 8 in an unpressed state according to an embodiment of the disclosure.

FIG. 10 is a schematic cross-sectional view illustrating the keycap shown in FIG. 8 in a pressed state according to an embodiment of the disclosure.

FIG. 11 is a schematic cross-sectional view of a key mechanism of a keyboard module according to still another embodiment of the disclosure.

FIG. 12 is a schematic cross-sectional view of a key mechanism of a keyboard module according to yet another embodiment of the disclosure.

FIG. 13 is a schematic cross-sectional view illustrating a keycap shown in FIG. 12 in a pressed state according to an embodiment of the disclosure.

FIG. 14 is a schematic view illustrating an equivalent circuit of the key mechanism, a display film, and a printed circuit board shown in FIG. 12 according to an embodiment of the disclosure.

FIG. 15 is a schematic cross-sectional view illustrating the keycap shown in FIG. 12 in an unpressed state according to an embodiment of the disclosure.

FIG. 16 is a schematic cross-sectional view of a key mechanism of a keyboard module according to a further embodiment of the disclosure.

FIG. 17 is a schematic cross-sectional view illustrating a keycap shown in FIG. 16 in an unpressed state according to an embodiment of the disclosure.

FIG. 18 is a schematic view illustrating an equivalent circuit of the key mechanism, a display film, and a printed circuit board shown in FIG. 16 according to an embodiment of the disclosure.

FIG. 19 is a schematic cross-sectional view illustrating the keycap shown in FIG. 16 in a pressed state according to an embodiment of the disclosure.

FIG. 20 is a schematic cross-sectional view illustrating the key mechanism shown in FIG. 16 according to another embodiment of the disclosure.

FIG. 21 is a schematic cross-sectional view illustrating the key mechanism shown in FIG. 16 according to still another embodiment of the disclosure.

### DESCRIPTION OF THE EMBODIMENTS

The term “coupling (or connection)” used in the full text of the disclosure (including the claims) can refer to any direct or indirect connection means. For example, if it is described in the text that the first device is coupled (or connected) to the second device, it should be interpreted as meaning that the first device can be directly connected to the second device, or that the first device can be indirectly connected to the second device by some other device or some means of connection. The terms “first” and “second” mentioned in the full text of the disclosure (including the claims) are used to name elements or to distinguish between different embodiments or ranges, and are not used to limit the upper or lower limit of the number of elements, nor are they used to limit the order of the elements. In addition, wherever possible, elements/components/steps using the same reference numbers in the drawings and embodiments represent the same or similar parts. Elements/components/steps that use the same reference numerals or use the same terms in different embodiments can be cross-referenced to the relevant descriptions.

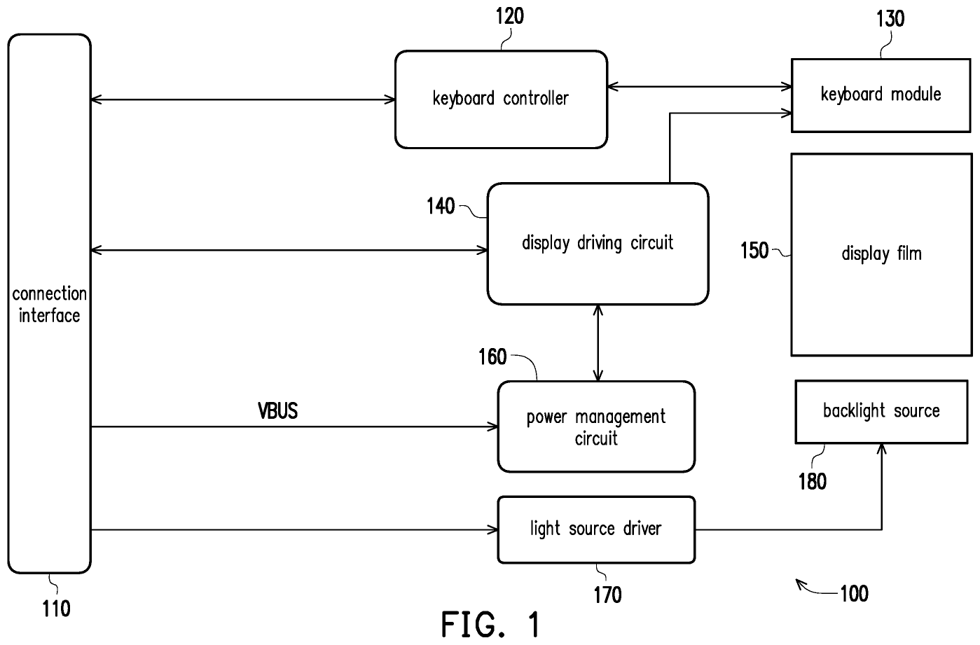

FIG. 1 is a schematic view of a circuit block of a keyboard apparatus 100 according to an embodiment of the disclosure. A connection interface 110 of the keyboard apparatus 100 may be connected to a host system. According to an actual design, the connection interface 110 may include a PS/2 interface, a universal serial bus (USB) interface, and/or other connection interfaces. The keyboard apparatus 100 also includes a keyboard controller 120 and a keyboard module 130. The keyboard module 130 includes multiple key mechanisms. The keyboard controller 120 may scan and sense (read) operating states of the key mechanisms to obtain a sensing result. The operating states include whether a key is pressed or not (i.e., whether a press event occurs). When any key of the keyboard module 130 is pressed, the keyboard controller 120 may transmit a corresponding interrupt signal of the pressed key to the host system (not shown) through the connection interface 110.

The keyboard apparatus 100 further includes a display driving circuit 140, a display film 150, a power management circuit 160, a light source driver 170, and a backlight source 180. The power management circuit 160 may be connected to a power line VBUS of the host system through the connection interface 110. Based on control of the display driving circuit 140, the power management circuit 160 may adjust a display driving voltage supplied to a pixel electrode. The host system (not shown) may control the display driving circuit 140 and the light source driver 170 through the connection interface 110. The light source driver 170 may drive the backlight source 180 to provide backlight to the display film 150. Based on control of the host system, the display driving circuit 140 may drive the pixel electrode disposed in the keyboard module 130 to cause the display film 150 to display one or more images. The images displayed by the display film 150 correspond to the key mechanisms of the keyboard module 130. For example, a user may see an image “P” displayed by the display film 150 through a key mechanism of the keyboard module 130, so the user may know that a definition (function) of the key mechanism is “letter P key”.

Depending on design requirements, the keyboard controller 120, the display driving circuit 140, and/or a press sensing circuit 121 (described later) of the keyboard controller 120 may be implemented in a form of hardware, firmware, software (i.e. program), or a combination of more than one of the above. In the hardware form, the keyboard controller 120, the display driving circuit 140, and/or the press sensing circuit 121 may be implemented in a logic circuit on an integrated circuit. Relevant functions of the keyboard controller 120, the display driving circuit 140, and/or the press sensing circuit 121 may be implemented as hardware using hardware description languages (e.g., Verilog HDL or VHDL) or other suitable programming languages. For example, the relevant functions of the keyboard controller 120, the display driving circuit 140, and/or the press sensing circuit 121 may be implemented in one or more controllers, microcontrollers, microprocessors, application-specific integrated circuit (ASIC), digital signal processor (DSP), field programmable gate array (FPGA), and/or various logic blocks, modules, and circuits in other processing units.

In the software and/or firmware form, the relevant functions of the keyboard controller 120, the display driving circuit 140, and/or the press sensing circuit 121 may be implemented as programming codes. For example, the keyboard controller 120, the display driving circuit 140, and/or the press sensing circuit 121 are implemented using general programming languages (e.g., C, C++, or a combination of languages) or other suitable programming languages. The programming codes may be recorded/stored in a “non-transitory computer readable medium”. In some embodiments, the non-transitory computer readable medium includes, for example, a read only memory (ROM), a tape, a disk, a card, a semiconductor memory, a programmable logic circuit and/or a storage device. The storage device includes a hard disk drive (HDD), a solid-state drive (SSD) or other storage devices. A central processing unit (CPU), a controller, a microcontroller, or a microprocessor may read and execute the programming codes from the non-transitory computer readable medium to implement the relevant functions of the keyboard controller 120, the display driving circuit 140 and (or) the press sensing circuit 121.

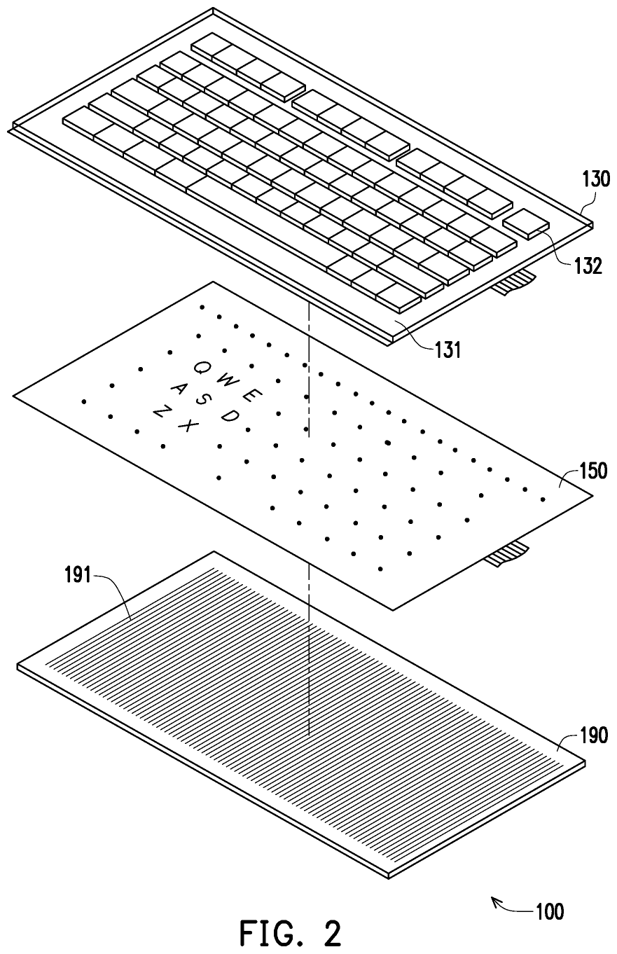

FIG. 2 is an exploded schematic view of the keyboard apparatus 100 according to an embodiment of the disclosure. Referring FIG. 1 and FIG. 2, FIG. 2 shows the keyboard module 130, the display film 150, and a printed circuit board 190 of the keyboard apparatus 100. The printed circuit board 190 includes at least one lower pixel electrode 191 disposed on the printed circuit board 190. The display driving circuit 140 may drive the lower pixel electrode 191. The keyboard module 130 includes a transparent substrate 131, at least one upper pixel electrode (not shown in FIG. 2), and multiple key mechanisms 132. The upper pixel electrode and the key mechanisms 132 are disposed on the transparent substrate 131. The display driving circuit 140 may drive the upper pixel electrode. The display film 150 is disposed between the printed circuit board 190 and the keyboard module 130. The display film 150 is adapted to be driven by the upper pixel electrode of the keyboard module 130 and the lower pixel electrode 191 of the printed circuit board 190 to display one or more images. This (or these) images are suitable for presentation through any one of the key mechanisms 132.

For example, the user may see an image “S” displayed by the display film 150 through a key mechanism 132 of the keyboard module 130, so the user may know that a definition (function) of the key mechanism is “letter S key”. In many application situations, the user can define the keys of the keyboard module 130 (change functions of the keys). When a definition/function of a key is changed, the host system (not shown) may control the display driving circuit 140 to change a display of the display film 150. For example, suppose a definition of one of the key mechanisms 132 of the keyboard module 130 is changed from “letter S key” to “rightward key”, the user may see through this key mechanism 132 that the image displayed by the display film 150 is changed from “S” to “→”. Therefore, the keyboard apparatus 100 has a changeable key display function.

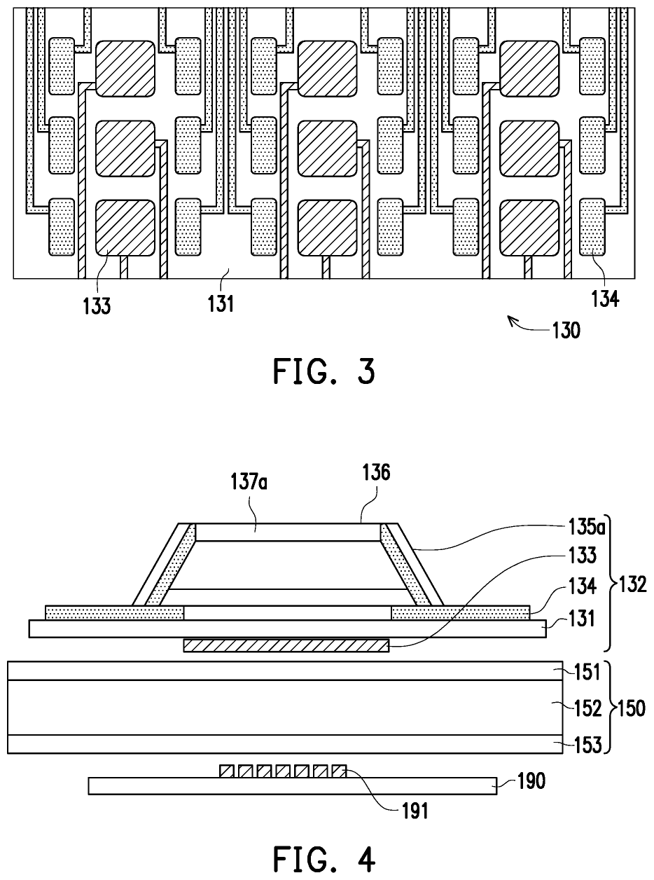

FIG. 3 is a schematic view of a layout of a transparent substrate 131 of the keyboard module 130 according to an embodiment of the disclosure. Referring FIG. 2 and FIG. 3, multiple upper pixel electrodes 133 are disposed on the transparent substrate 131 corresponding to locations of the multiple key mechanisms 132 of the keyboard module 130. In addition, multiple conductive pads 134 are also disposed on the transparent substrate 131. The upper pixel electrode 133 and the conductive pad 134 may be electrically connected to the display driving circuit 140 and/or the keyboard controller 120.

FIG. 4 is a schematic cross-sectional view of a key mechanism 132 of the keyboard module 130 according to an embodiment of the disclosure. Referring FIG. 2, FIG. 3, and FIG. 4, the transparent substrate 131, the key mechanism 132, the upper pixel electrode 133, the conductive pad 134, the display film 150, the printed circuit board 190, and the lower pixel electrode 191 shown in FIG. 4 may be referred to relevant descriptions of FIG. 1 to FIG. 3. According to the embodiment shown in FIG. 4, the display film 150 includes a display substrate 151, a display layer 152, and a display substrate 153. The display substrate 151 and the display substrate 153 are different from the printed circuit board 190 and the transparent substrate 131. The display layer 152 is disposed between the display substrate 151 and the display substrate 153. According to actual design, in some embodiments, the display layer 152 may include a bistable display material, a multi-stable display material, an electronic paper material, or other display films. According to actual design, the bistable display film may include Eink electronic paper material, polymer-dispersed liquid crystal (PDLC), surface-stabilized cholesteric texture (SSCT) liquid crystal, ferroelectric liquid crystal (FLC) or other display film.

The host system (not shown) may select the key mechanism 132 shown in FIG. 4 as a target key mechanism and drive the display layer 152 to change the image corresponding to the target key mechanism. As shown in FIG. 4, in a vertical projection of the transparent substrate 131, the target key mechanism 132 overlaps a corresponding upper pixel electrode 133 and a corresponding lower pixel electrode 191. The host system (not shown) may control the display driving circuit 140 to change the display of the display film 150. For example, during a display driving period of the target key mechanism 132, a first display driving voltage is applied to the corresponding upper pixel electrode 133, and a second display driving voltage is applied to the corresponding lower pixel electrode 191, causing the display film 150 between the corresponding upper pixel electrode 133 and the corresponding lower pixel electrode 191 to display a corresponding image below the target key mechanism 132.

The key mechanism 132 shown in FIG. 4 also includes a keycap 135a and a transparent electrode 137a. The keycap 135a may be a conductive elastic keycap. A material of the conductive elastic keycap 135a may include transparent rubber, soft film or other conductive elastic materials. The keycap 135a is disposed on a first surface of the transparent substrate 131, and the upper pixel electrode 133 is disposed on a second surface of the transparent substrate 131. According to design requirements, in other embodiments, the keycap 135a and the upper pixel electrode 133 may be disposed on the first surface of the transparent substrate 131. As shown in FIG. 4, in the vertical projection of the transparent substrate 131, the keycap 135a overlaps a corresponding upper pixel electrode 133 and a corresponding lower pixel electrode 191. The keycap 135a has a transparent window 136, which is suitable for seeing the image displayed by the display film 150. The transparent electrode 137a is disposed in the keycap 135a. The transparent electrode 137a includes a transparent membrane and a conductive electrode. The transparent electrode 137a is electrically connected to the conductive pad 134. The transparent electrode 137a and a corresponding upper pixel electrode 133 form a press sensing capacitor to sense a press operation on the keycap 135a.

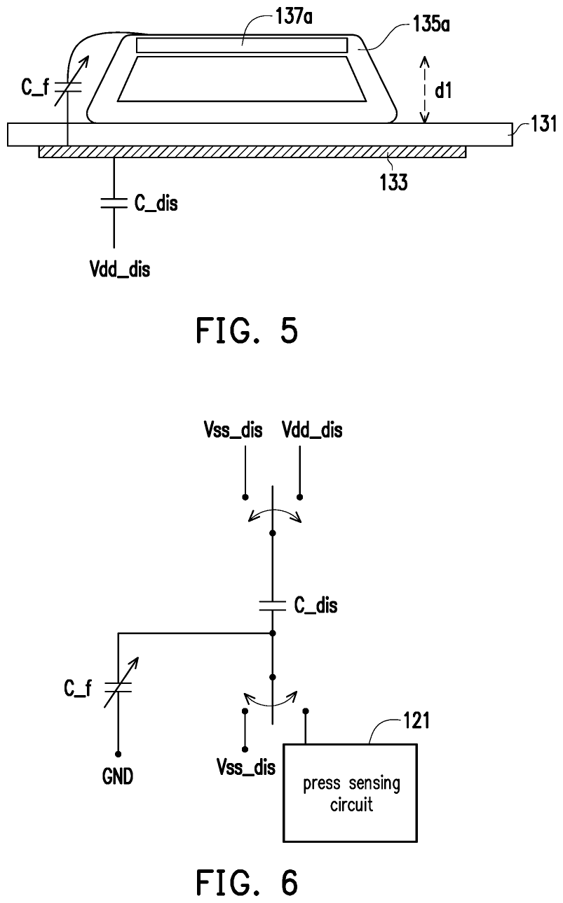

FIG. 5 is a schematic cross-sectional view illustrating the keycap 135a shown in FIG. 4 in an unpressed state according to an embodiment of the disclosure. FIG. 6 is a schematic view illustrating an equivalent circuit of the key mechanism 132, the display film 150, and the printed circuit board 190 shown in FIG. 4 according to an embodiment of the disclosure. Referring to FIG. 4, FIG. 5, and FIG. 6, a distance between the upper pixel electrode 133 and the transparent electrode 137a is d1, so that the upper pixel electrode 133 and the transparent electrode 137a form a press sensing capacitor C_f. The upper pixel electrode 133 and the lower pixel electrode 191 form a display pixel capacitor C_dis. During a display driving period, a display driving voltage Vss_dis is applied to the upper pixel electrode 133 (one end of the display pixel capacitor C_dis), and a display driving voltage Vdd_dis is applied to the lower pixel electrode 191 (the other end of the display pixel capacitor C_dis), causing the display film 150 between the upper pixel electrode 133 and the lower pixel electrode 191 to present a corresponding image below the key mechanism 132. Voltage levels of the display driving voltage Vss_dis and the display driving voltage Vdd_dis may be determined according to actual design requirements and characteristics of the display film 150.

A reference voltage (e.g., a ground voltage GND) is applied to the transparent electrode 137a of the keycap 135a. A press sensing period (a press sensing operation) of the key mechanism 132 may include a first sub-period and a second sub-period. In the first sub-period of the keycap 135a, a touch driving voltage (e.g., the first display driving voltage Vss_dis or other voltages different from the ground voltage GND) is applied to the upper pixel electrode 133 and the lower pixel electrode 191 (both ends of the display pixel capacitor C_dis), at which time the press sensing capacitor C_f is charged. In the second sub-period of the keycap 135a, the press sensing circuit 121 of the keyboard controller 120 is selectively coupled to the upper pixel electrode 133 to sense the upper pixel electrode 133 (one end of the press sensing capacitor C_f), and the lower pixel electrode 191 is electrically floating.

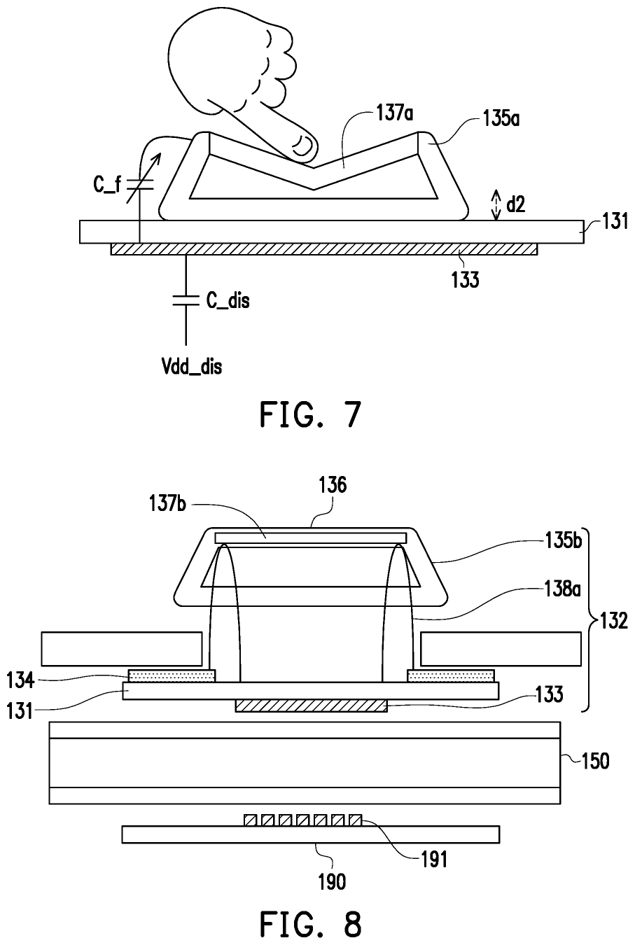

FIG. 7 is a schematic cross-sectional view illustrating the keycap 135a shown in FIG. 4 in a pressed state according to an embodiment of the disclosure. When the keycap 135a is pressed, a distance between the upper pixel electrode 133 and the transparent electrode 137a is shortened from d1 to d2 because of deformation of the keycap 135a, i.e., capacitance of the press sensing capacitor C_f becomes larger. Therefore, the press sensing circuit 121 may sense a change in capacitance of the press sensing capacitor C_f so that the keyboard controller 120 may determine whether a press event has occurred on the key mechanism 132 shown in FIG. 4.

FIG. 8 is a schematic cross-sectional view of a key mechanism 132 of the keyboard module 130 according to another embodiment of the disclosure. Referring FIG. 2, FIG. 3, and FIG. 8, the transparent substrate 131, the key mechanism 132, the upper pixel electrode 133, the conductive pad 134, the display film 150, the printed circuit board 190, and the lower pixel electrode 191 shown in FIG. 8 may be referred to relevant descriptions of FIG. 1 to FIG. 3. The transparent substrate 131, the upper pixel electrode 133, the conductive pad 134, a keycap 135b, a transparent electrode 137b, the display film 150, the printed circuit board 190, and the lower pixel electrode 191 shown in FIG. 8 may be referred to relevant descriptions of the transparent substrate 131, the upper pixel electrode 133, the conductive pad 134, the keycap 135a, the transparent electrode 137a, the display film 150, the printed circuit board 190, and the lower pixel electrode 191 shown in FIG. 4, so will not be described in detail. According to the embodiment shown in FIG. 8, the key mechanism 132 further includes a conductive rubber dome 138a. When the keycap 135b is pressed, the keycap 135b sinks closer to the transparent substrate 131 because of deformation of the conductive rubber dome 138a.

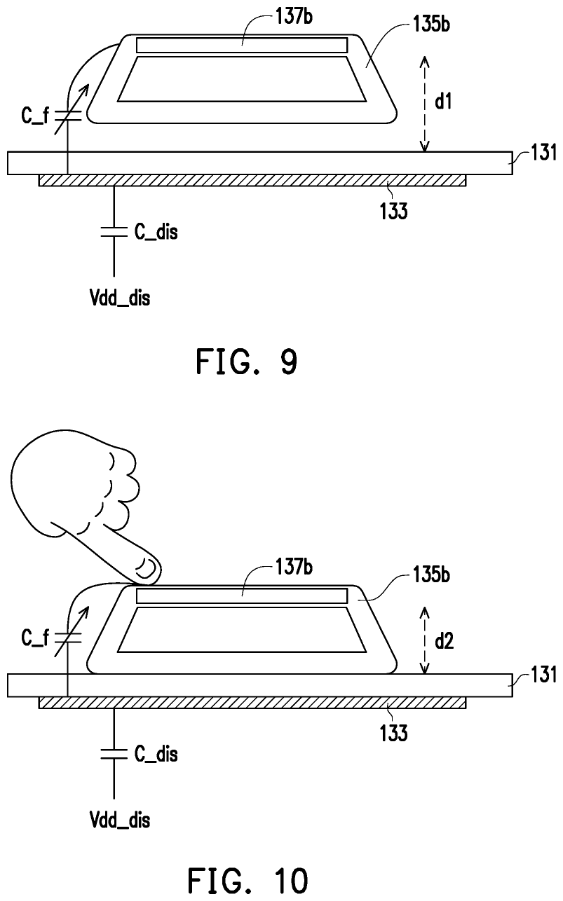

FIG. 9 is a schematic cross-sectional view illustrating the keycap 135b shown in FIG. 8 in an unpressed state according to an embodiment of the disclosure. FIG. 6 may also be regarded as a schematic view of an equivalent circuit of the key mechanism 132, the display film 150, and the printed circuit board 190 shown in FIG. 8. Referring FIG. 6, FIG. 8, and FIG. 9, the upper pixel electrode 133 and the lower pixel electrode 191 form the display pixel capacitor C_dis. A distance between the upper pixel electrode 133 and the transparent electrode 137b is d1, so that the upper pixel electrode 133 and the transparent electrode 137b form a press sensing capacitor C_f. During a display driving period, a first display driving voltage Vss_dis is applied to the upper pixel electrode 133 (one end of the display pixel capacitor C_dis), and a second display driving voltage Vdd_dis is applied to the lower pixel electrode 191 (the other end of the display pixel capacitor C_dis), causing the display film 150 between the upper pixel electrode 133 and the lower pixel electrode 191 to present a corresponding image below the key mechanism 132. Voltage levels of the first display driving voltage Vss_dis and the second display driving voltage Vdd_dis may be determined according to actual design requirements and characteristics of the display film 150.

A reference voltage (e.g., a ground voltage GND) is applied to the transparent electrode 137b of the keycap 135b. A press sensing period (a press sensing operation) of the key mechanism 132 may include a first sub-period and a second sub-period. In the first sub-period of the keycap 135b, a touch driving voltage (e.g., the first display driving voltage Vss_dis or other voltages different from the ground voltage GND) is applied to the upper pixel electrode 133 and the lower pixel electrode 191 (both ends of the display pixel capacitor C_dis), at which time the press sensing capacitor C_f is charged. In the second sub-period of the keycap 135b, the press sensing circuit 121 of the keyboard controller 120 is coupled to the upper pixel electrode 133 to sense the upper pixel electrode 133 (one end of the press sensing capacitor C_f), and the lower pixel electrode 191 is electrically floating.

FIG. 10 is a schematic cross-sectional view illustrating the keycap 135b shown in FIG. 8 in a pressed state according to an embodiment of the disclosure. When the keycap 135b is pressed, the keycap 135b sinks closer to the transparent substrate 131 because of deformation of the conductive rubber dome 138a, i.e. a distance between the upper pixel electrode 133 and the transparent electrode 137b is shortened from d1 to d2 (capacitance of the press sensing capacitor C_f becomes larger). Therefore, the press sensing circuit 121 may sense a change in capacitance of the press sensing capacitor C_f so that the keyboard controller 120 may determine whether a press event has occurred on the key mechanism 132 shown in FIG. 8.

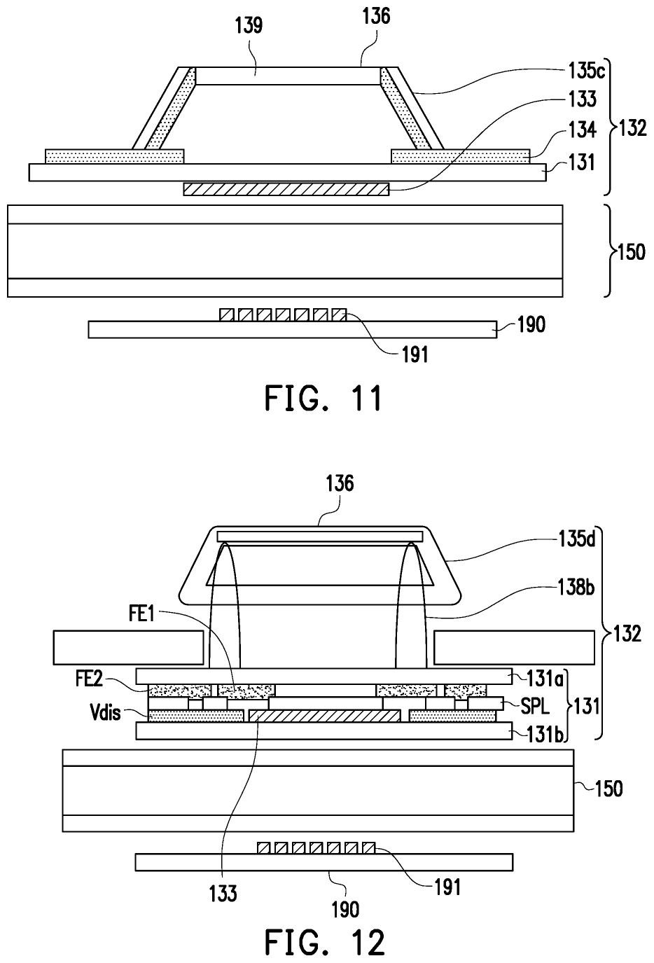

FIG. 11 is a schematic cross-sectional view of the key mechanism 132 of the keyboard module according to still another embodiment of the disclosure. Referring FIG. 2, FIG. 3, and FIG. 11, the transparent substrate 131, the key mechanism 132, the upper pixel electrode 133, the conductive pad 134, the display film 150, the printed circuit board 190, and the lower pixel electrode 191 shown in FIG. 11 may be referred to relevant descriptions of FIG. 1 to FIG. 3. The transparent substrate 131, the upper pixel electrode 133, the conductive pad 134, a keycap 135c, the transparent window 136, the display film 150, the printed circuit board 190, and the lower pixel electrode 191 shown in FIG. 11 may be referred to relevant descriptions of the transparent substrate 131, the upper pixel electrode 133, the conductive pad 134, the keycap 135a, the transparent window 136, the display film 150, the printed circuit board 190, and the lower pixel electrode 191 shown in FIG. 4, so will not be described in detail.

According to the embodiment shown in FIG. 11, the key mechanism 132 further includes a transparent variable resistance material 139. The transparent variable resistance material 139 is disposed on the transparent window 136 of the keycap 135c. The transparent variable resistance material 139 is electrically connected to the conductive pad 134. When the keycap 135c is pressed, the transparent variable resistance material 139 has a first resistance state due to deformation. When the keycap 135c is not pressed, the transparent variable resistance material 139 has a second resistance state due to return to an original state of the transparent variable resistance material 139. Therefore, the keyboard controller 120 may sense a change in resistance value of the transparent variable resistance material 139, allowing the keyboard controller 120 to determine whether a press event has occurred on the key mechanism 132 shown in FIG. 11.

FIG. 12 is a schematic cross-sectional view of the key mechanism 132 of the keyboard module 130 according to yet another embodiment of the disclosure. The transparent substrate 131, the key mechanism 132, the upper pixel electrode 133, the display film 150, the printed circuit board 190, and the lower pixel electrode 191 shown in FIG. 12 may be referred to the relevant descriptions of FIG. 1 to FIG. 3. Referring FIG. 2, FIG. 3, and FIG. 12, according to the embodiment shown in FIG. 12, the transparent substrate 131 includes a transparent substrate 131a and a transparent substrate 131b. The key mechanism 132 shown in FIG. 12 further includes a keycap 135d, a rubber dome 138b, a spacer layer SPL, a display driving voltage electrode Vdis, a flexible electrode FE1, and a flexible electrode FE2.

The keycap 135d is disposed above the transparent substrate 131a. In a vertical projection of the transparent substrate 131, the keycap 135d overlaps the upper pixel electrode 133 and the lower pixel electrode 191 corresponding to the keycap 135d. The keycap 135d has the transparent window 136, which is suitable for seeing the image displayed by the display film 150. The spacer layer SPL is disposed between the transparent substrate 131a and the transparent substrate 131b. The upper pixel electrode 133 and the display driving voltage electrode Vdis are disposed in a first conductive layer between the spacer layer SPL and the transparent substrate 131b. According to actual design, the display driving voltage electrode Vdis may be regarded as an embodiment of the conductive pad 134 shown in FIG. 3.

The flexible electrode FE1 and the flexible electrode FE2 are disposed in a second conductive layer between the spacer layer SPL and the transparent substrate 131a. The flexible electrode FE1 may be regarded as a first press sensing electrode, and the flexible electrode FE2 may be regarded as a second press sensing electrode. The flexible electrode FE2 may sense a press operation on the keycap 135d. When the keycap 135d undergoes a press operation, press force is applied to the transparent substrate 131a through the rubber dome 138b, resulting in deformation of the flexible electrode FE1 and the flexible electrode FE2. Therefore, when the keycap 135d undergoes a press operation, the flexible electrode FE1 electrically contacts the display driving voltage electrode Vdis and the upper pixel electrode 133 due to deformation, resulting in the display driving voltage Vss_dis of the display driving voltage electrode Vdis being applied to the upper pixel electrode 133 through the flexible electrode FE1. Similarly, when the keycap 135d undergoes a press operation, the flexible electrode FE2 (the second press sensing electrode) electrically contacts the display driving voltage electrode Vdis (the first press sensing electrode) due to deformation, resulting in the display driving voltage Vss_dis being applied to the flexible electrode FE2. When the keycap 135d does not undergo a press operation, the flexible electrode FE1 does not electrically contact the display driving voltage electrode Vdis and the upper pixel electrode 133 due to return to an original state of the flexible electrode FE1, and the flexible electrode FE2 (the second press sensing electrode) does not electrically contact the display driving voltage electrode Vdis (the first press sensing electrode) due to return to an original state of the flexible electrode FE2.

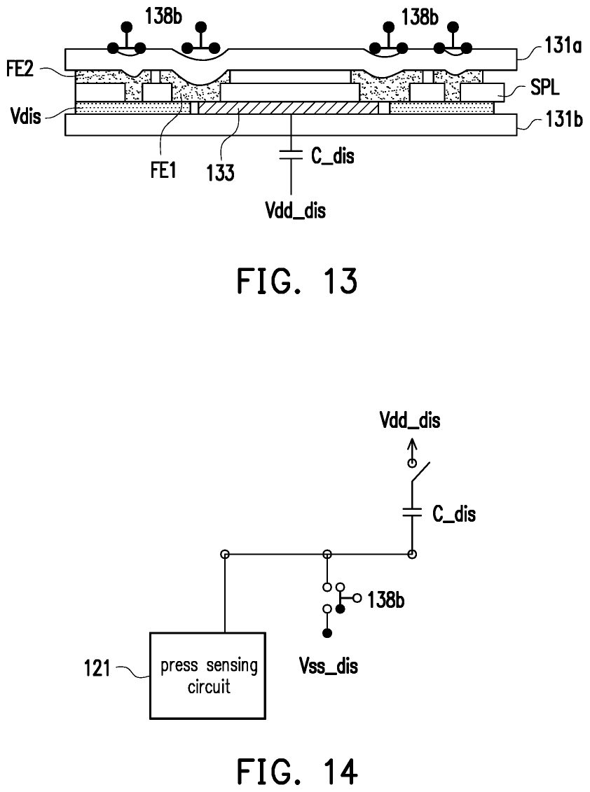

FIG. 13 is a schematic cross-sectional view illustrating the keycap 135d shown in FIG. 12 in a pressed state according to an embodiment of the disclosure. FIG. 14 is a schematic view illustrating an equivalent circuit of the key mechanism 132, the display film 150, and the printed circuit board 190 shown in FIG. 12 according to an embodiment of the disclosure. Referring FIG. 12, FIG. 13, and FIG. 14, the upper pixel electrode 133 and the lower pixel electrode 191 form a display pixel capacitor C_dis. When the keycap 135d undergoes a press operation, the flexible electrode FE1 electrically contacts the display driving voltage electrode Vdis and a corresponding upper pixel electrode due to deformation. Therefore, the display driving voltage Vss_dis of the display driving voltage electrode Vdis may be applied to the upper pixel electrode 133 (one end of the display pixel capacitor C_dis). At this time, the display driving voltage Vdd_dis is applied to the lower pixel electrode 191 (the other end of the display pixel capacitor C_dis), causing the display film 150 between the upper pixel electrode 133 and the lower pixel electrode 191 to present a corresponding image below the key mechanism 132.

In addition, the press sensing circuit 121 of the keyboard controller 120 is coupled to the flexible electrode FE2. When the keycap 135d undergoes a press operation, the flexible electrode FE2 electrically contacts the display driving voltage electrode Vdis due to deformation, resulting in the display driving voltage Vss_dis of the display driving voltage electrode Vdis being applied to the flexible electrode FE2. The press sensing circuit 121 may detect the display driving voltage Vss_dis of the flexible electrode FE2 to determine whether a press event has occurred on the keycap 135d.

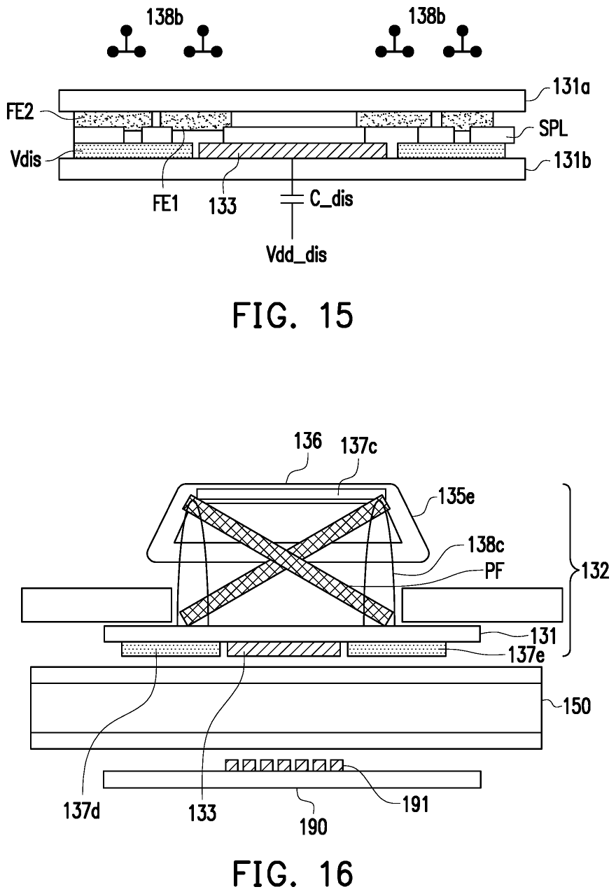

FIG. 15 is a schematic cross-sectional view illustrating the keycap 135d shown in FIG. 12 in an unpressed state according to an embodiment of the disclosure. When the keycap 135d does not undergo a press operation, the flexible electrode FE1 does not electrically contact the display driving voltage electrode Vdis and the upper pixel electrode 133 due to return to an original state of the flexible electrode FE1, resulting in the display driver voltage Vss_dis not being applied to the upper pixel electrode 133. At this time, the driving voltage Vdd_dis is not applied to the lower pixel electrode 191. In addition, when the keycap 135d does not undergo a press operation, the flexible electrode FE2 does not electrically contact the display driving voltage electrode Vdis due to return to an original state of the flexible electrode FE2, resulting in the display driving voltage Vss_dis not being applied to the flexible electrode FE2. The press sensing circuit 121 may detect a voltage of the flexible electrode FE2 to determine whether a press event has occurred on the keycap 135d.

FIG. 16 is a schematic cross-sectional view of the key mechanism 132 of the keyboard module 130 according to a further embodiment of the disclosure. The transparent substrate 131, the key mechanism 132, the upper pixel electrode 133, the display film 150, the printed circuit board 190, and the lower pixel electrode 191 shown in FIG. 16 may be referred to relevant descriptions of FIG. 1 to FIG. 3. The upper pixel electrode 133, the display film 150, the printed circuit board 190, and the lower pixel electrode 191 shown in FIG. 16 may be referred to relevant description of FIG. 4. Referring FIG. 2, FIG. 3, and FIG. 16, according to the embodiment shown in FIG. 16, the key mechanism 132 further includes a keycap 135e, a transparent electrode 137c, a transparent electrode 137d, a transparent electrode 137e, a rubber dome 138c, and a pressure foot PF.

The keycap 135e is disposed on a first surface of the transparent substrate 131, and the upper pixel electrode 133 is disposed on a second surface of the transparent substrate 131. In a vertical projection of the transparent substrate 131, the keycap 135e overlaps the upper pixel electrode 133 and the lower pixel electrode 191 corresponding to the keycap 135e. The keycap 135e has the transparent window 136, which is suitable for seeing the image displayed by the display film 150. The transparent electrode 137c is disposed in the keycap 135e. The transparent electrode 137d and the transparent electrode 137e are disposed on the second surface of the transparent substrate 131. According to actual design, the transparent electrode 137d and (or) the transparent electrode 137e may be regarded as an embodiment of the conductive pad 134 shown in FIG. 3.

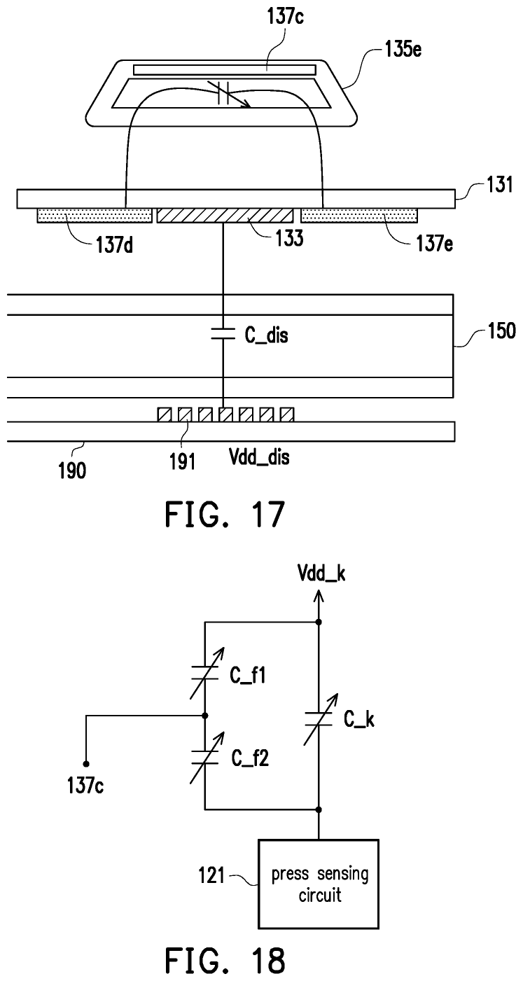

FIG. 17 is a schematic cross-sectional view illustrating the keycap 135e shown in FIG. 16 in an unpressed state according to an embodiment of the disclosure. FIG. 18 is a schematic view illustrating an equivalent circuit of the key mechanism 132, the display film 150, and the printed circuit board 190 shown in FIG. 16 according to an embodiment of the disclosure. Referring FIG. 16, FIG. 17, and FIG. 18, the upper pixel electrode 133 and the lower pixel electrode 191 form a display pixel capacitor C_dis. During a display driving period, the display driving voltage Vss_dis is applied to the upper pixel electrode 133 (one end of the display pixel capacitor C_dis), and the second display driving voltage Vdd_dis is applied to the lower pixel electrode 191 (the other end of the display pixel capacitor C_dis), causing the display film 150 between the upper pixel electrode 133 and the lower pixel electrode 191 to present a corresponding image below the key mechanism 132.

The transparent electrode 137d and the transparent electrode 137e form a press sensing capacitor C_k. The transparent electrode 137c and the transparent electrode 137d form a press sensing capacitor C_f1. The transparent electrode 137c and the transparent electrode 137e form a press sensing capacitor C_f2. The press sensing capacitors C_k, C_f1, and C_f2 may sense a press operation on the keycap 135e. During a press sensing period of the keycap 135e, a touch driving voltage Vdd_k is applied to the transparent electrode 137d (a first end of the press sensing capacitor C_f1), and the press sensing circuit 121 of the keyboard controller 120 is selectively electrically connected to the transparent electrode 137e (a first end of the press sensing capacitor C_f2) to sense the press operation on the keycap 135e. A level of the touch driving voltage Vdd_k may be determined according to actual design.

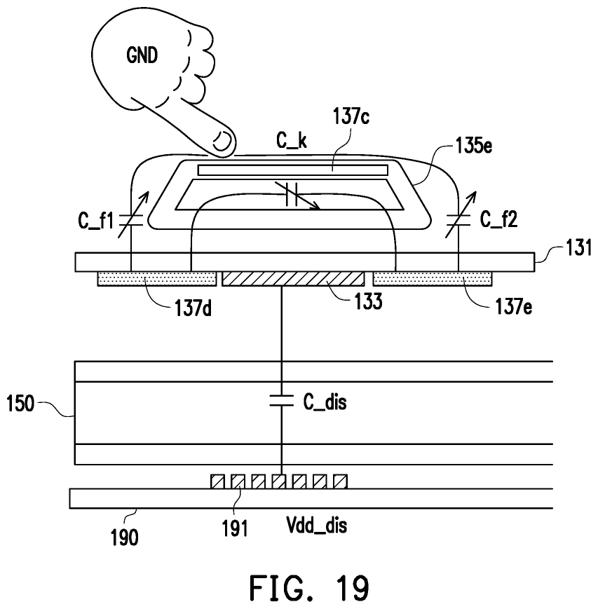

FIG. 19 is a schematic cross-sectional view illustrating the keycap 135e shown in FIG. 16 in a pressed state according to an embodiment of the disclosure. When the keycap 135e is pressed, a distance between the transparent electrode 137c and the transparent electrode 137d (137e) is shortened because the keycap 135e sinks (the keycap 135e is closer to the transparent substrate 131), i.e. capacitance of the press sensing capacitor C_f1 (C_f2) becomes larger. Therefore, the press sensing circuit 121 may sense a change in total capacitance of the press sensing capacitors C_k, C_f1 and C_f2 so that the keyboard controller 120 may determine whether a press event has occurred on the key mechanism 132 shown in FIG. 16

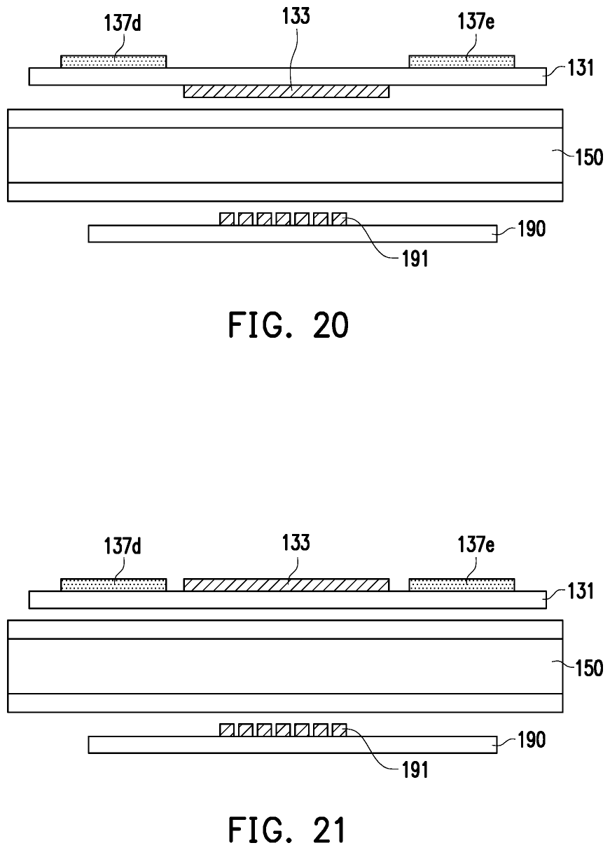

FIG. 20 is a schematic cross-sectional view illustrating the key mechanism 132 shown in FIG. 16 according to another embodiment of the disclosure. The upper pixel electrode 133, the display film 150, the printed circuit board 190, and the lower pixel electrode 191 shown in FIG. 20 may be referred to relevant descriptions of FIG. 16. According to the embodiment shown in FIG. 20, the transparent electrode 137d and the transparent electrode 137e are disposed on the first surface of the transparent substrate 131, and the upper pixel electrode 133 is disposed on the second surface of the transparent substrate 131.

FIG. 21 is a schematic cross-sectional view illustrating the key mechanism 132 shown in FIG. 16 according to still another embodiment of the disclosure. The upper pixel electrode 133, the display film 150, the printed circuit board 190, and the lower pixel electrode 191 shown in FIG. 21 may be referred to relevant descriptions of FIG. 16. According to the embodiment shown in FIG. 21, the upper pixel electrode 133, the transparent electrode 137d, and the transparent electrode 137e are all disposed on the first surface of the transparent substrate 131.

In summary, the keyboard apparatus 100 according to the embodiments has a display film 150. The multiple key mechanisms 132 of the keyboard module 130 may share the display film 150, i.e., the display film 150 may present images to the user through any of the key mechanisms 132. When the system (not shown) changes a definition (function) of a key of the key mechanisms 132, the system may change an image/graphic presentation of the key by driving the display film 150. Therefore, the keyboard apparatus 100 has a changeable key display function.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

1. A keyboard apparatus comprising:
a printed circuit board comprising at least one lower pixel electrode disposed on the printed circuit board;
a keyboard module comprising a transparent substrate, at least one upper pixel electrode, and a plurality of key mechanisms, wherein the at least one upper pixel electrode and the key mechanisms are disposed on the transparent substrate; and
a display film disposed between the at least one lower pixel electrode of the printed circuit board and the at least one upper pixel electrode of the keyboard module, wherein the display film is adapted to be driven by the at least one upper pixel electrode of the keyboard module and the at least one lower pixel electrode of the printed circuit board to display at least one image, and the at least one image is suitable for presentation through any one of the key mechanisms;
wherein the display film comprises:
a first display substrate;
a second display substrate; and
a display layer disposed between the first display substrate and the second display substrate;
wherein the first display substrate and the second display substrate are different from the printed circuit board and the transparent substrate.

2. The keyboard apparatus according to claim 1, wherein the display layer comprises a bistable display material or an electronic paper material.

3. The keyboard apparatus according to claim 1, wherein the key mechanisms comprise a target key mechanism, wherein the target key mechanism overlaps a corresponding upper pixel electrode of the at least one upper pixel electrode and a corresponding lower pixel electrode of the at least one lower pixel electrode in a vertical projection of the transparent substrate, and
during a display driving period of the target key mechanism, a first display driving voltage is applied to the corresponding upper pixel electrode, and a second display driving voltage is applied to the corresponding lower pixel electrode, causing the display film to present a corresponding image below the target key mechanism.

4. The keyboard apparatus according to claim 1, wherein the any one of the key mechanisms comprises:
a keycap having a transparent window suitable for seeing the at least one image displayed by the display film, wherein the keycap is disposed on a first surface of the transparent substrate, the keycap overlaps a corresponding upper pixel electrode of the at least one upper pixel electrode and a corresponding lower pixel electrode of the at least one lower pixel electrode in a vertical projection of the transparent substrate; and
a transparent electrode disposed in the keycap, wherein the transparent electrode and the corresponding upper pixel electrode form a press sensing capacitor for sensing a press operation on the keycap.

5. The keyboard apparatus according to claim 4, wherein the at least one upper pixel electrode is disposed on the first surface of the transparent substrate.

6. The keyboard apparatus according to claim 4, wherein the at least one upper pixel electrode is disposed on a second surface of the transparent substrate opposite to the first surface.

7. The keyboard apparatus according to claim 4, wherein a reference voltage is applied to the transparent electrode of the keycap, and a press sensing period of the keycap comprises a first sub-period and a second sub-period,
wherein during the first sub-period of the keycap, a touch driving voltage is applied to the corresponding upper pixel electrode and the corresponding lower pixel electrode; and
during the second sub-period of the keycap, a press sensing circuit senses the corresponding upper pixel electrode, wherein the corresponding lower pixel electrode is floating.

8. The keyboard apparatus according to claim 1, wherein the any one of the key mechanisms comprises:
a keycap having a transparent window suitable for seeing the at least one image displayed by the display film, wherein the keycap is disposed above a first surface of the transparent substrate, and the keycap overlaps a corresponding upper pixel electrode of the at least one upper pixel electrode and a corresponding lower pixel electrode of the at least one lower pixel electrode in a vertical projection of the transparent substrate;
a first transparent electrode disposed in the keycap;
a second transparent electrode disposed on the transparent substrate, wherein the first transparent electrode and the second transparent electrode form a first press sensing capacitor for sensing a press operation on the keycap; and
a third transparent electrode disposed on the transparent substrate, wherein the first transparent electrode and the third transparent electrode form a second press sensing capacitor for sensing the press operation on the keycap.

9. The keyboard apparatus according to claim 8, wherein:
during a press sensing period of the keycap, a touch driving voltage is applied to the second transparent electrode, and a press sensing circuit is selectively electrically connected to the third transparent electrode to sense the press operation on the keycap.

10. The keyboard apparatus according to claim 8, wherein the second transparent electrode and the third transparent electrode are disposed on the first surface of the transparent substrate.

11. The keyboard apparatus according to claim 8, wherein the second transparent electrode and the third transparent electrode are disposed on a second surface of the transparent substrate opposite to the first surface.

12. The keyboard apparatus according to claim 8, wherein the at least one upper pixel electrode is disposed on the first surface of the transparent substrate.

13. The keyboard apparatus according to claim 8, wherein the at least one upper pixel electrode is disposed on a second surface of the transparent substrate opposite to the first surface.

14. The keyboard apparatus according to claim 1, wherein the any one of the key mechanisms comprises:
a keycap having a transparent window suitable for seeing the at least one image displayed by the display film, wherein the keycap is disposed on a first surface of the transparent substrate, and the keycap overlaps a corresponding upper pixel electrode of the at least one upper pixel electrode and a corresponding lower pixel electrode of the at least one lower pixel electrode in a vertical projection of the transparent substrate;
a transparent variable resistance material disposed in the transparent window of the keycap, wherein when the keycap undergoes a press operation, the transparent variable resistance material has a first resistance state due to deformation, and when the keycap does not undergo the press operation, the transparent variable resistance material has a second resistance state due to return to an original state of the transparent variable resistance material.

15. The keyboard apparatus according to claim 1, wherein the transparent substrate comprises a first transparent substrate and a second transparent substrate, and the any one of the key mechanisms comprises:
a keycap disposed above the first transparent substrate, wherein the keycap overlaps a corresponding upper pixel electrode of the at least one upper pixel electrode and a corresponding lower pixel electrode of the at least one lower pixel electrode in a vertical projection of the transparent substrate;
a spacer layer disposed between the first transparent substrate and the second transparent substrate, wherein the corresponding upper pixel electrode is disposed on a first conductive layer between the spacer layer and the second transparent substrate;
a first display driving voltage electrode disposed on the first conductive layer; and
a first flexible electrode disposed on a second conductive layer between the spacer layer and the first transparent substrate.

16. The keyboard apparatus according to claim 15, wherein:
when the keycap undergoes a press operation, the first flexible electrode electrically contacts the first display driving voltage electrode and the corresponding upper pixel electrode due to deformation, resulting in a first display driving voltage of the first display driving voltage electrode being applied to the corresponding upper pixel electrode, and
when the keycap does not undergo the press operation, the first flexible electrode does not electrically contact the first display driving voltage electrode and the corresponding upper pixel electrode due to return to an original state of the first flexible electrode, resulting in the first display driving voltage not being applied to the corresponding upper pixel electrode.

17. The keyboard apparatus according to claim 16, wherein:
when the keycap undergoes the press operation, a second display driving voltage is applied to the corresponding lower pixel electrode, causing the display film to present a corresponding image below the keycap, and
when the keycap does not undergo the press operation, the second display driving voltage is not applied to the corresponding lower pixel electrode.

18. The keyboard apparatus according to claim 16, wherein the any one of the key mechanisms further comprises:
a second flexible electrode disposed on the second conductive layer for sensing the press operation on the keycap, wherein,
when the keycap undergoes the press operation, the second flexible electrode electrically contacts the first display driving voltage electrode due to defoimation, resulting in the first display driving voltage being applied to the second flexible electrode, and
when the keycap does not undergo the press operation, the second flexible electrode does not electrically contact the first display driving voltage electrode due to return to an original state of the second flexible electrode, resulting in the first display driving voltage not being applied to the second flexible electrode.

19. The keyboard apparatus according to claim 1, wherein the transparent substrate comprises a first transparent substrate and a second transparent substrate, and the any one of the key mechanisms comprises:
a keycap disposed above the first transparent substrate, wherein the keycap overlaps a corresponding upper pixel electrode of the at least one upper pixel electrode and a corresponding lower pixel electrode of the at least one lower pixel electrode in a vertical projection of the transparent substrate;
a spacer layer disposed between the first transparent substrate and the second transparent substrate, wherein the corresponding upper pixel electrode is disposed on a first conductive layer between the spacer layer and the second transparent substrate;
a first press sensing electrode disposed on the first conductive layer; and
a second press sensing electrode disposed on a second conductive layer between the spacer layer and the first transparent substrate.

20. The keyboard apparatus according to claim 19, wherein,
when the keycap undergoes a press operation, the second press sensing electrode electrically contacts the first press sensing electrode due to deformation, and
when the keycap does not undergo the press operation, the second press sensing electrode does not electrically contact the first press sensing electrode due to return to an original state of the second press sensing electrode.
